(19) United States
(12) Patent Application Publication
(10) Pub. No.: US 2016/0084880 A1
(43) Pub. Date: Mar. 24, 2016

(54) INTEGRATED STRIKE PLATE SOCKET

(71) Applicant: QUALCOMM Incorporated, San Diego, CA (US)

(72) Inventors: Rae-Ann LoCicero, La Jolla, CA (US); Keith Barry, San Diego, CA (US); Anthony Newman, San Diego, CA (US)

(21) Appl. No.: 14/493,265

(22) Filed: Sep. 22, 2014

(51) Int. Cl. G01R 1/04; G01R 31/28

(52) U.S. Cl. CPC G01R 1/0433; G01R 31/2886

(57) ABSTRACT

An apparatus and method for facilitating testing of an electronic device is provided. The apparatus includes a strike plate with an integrated socket. Alignment dowels are located on an outside rim of the integrated strike plate and socket. Shims are located in a recess in the outside rim of the integrated strike plate and socket and may be used to adjust the height of the assembly to facilitate handling by an automated test handler. The apparatus further includes a memory nest assembly having a receptacle for retaining an electronic device to be tested. In addition, the memory nest assembly is formed to mate with the socket on the integrated strike plate.

### FIELD

The present disclosure relates generally to automated handler-based testing of integrated circuit (IC) products and more particularly to a change kit guide/strike plate integrated directly into the test socket frame.

### BACKGROUND

Automated handlers are often used to test IC products in an efficient and thorough manner. The automated handlers maneuver the ICs using a combination of strike plates and sockets that are typically stacked together. The stacked assembly is then moved through the testing process. The assembly may include a change kit strike plate and a socket frame that are separate pieces which are stacked on top of each other.

Both the overall complexity and the stack up are increased because the change kit strike plate and socket frame are separate pieces. In some cases, the automated handling device is manufactured by one company and the change kit and strike plate are manufactured by another company. This may lead to problems in preparing ICs for automated handler testing. The stack up involves two separate parts, a socket and a strike plate which are stacked together. Each piece is build to specific dimensions, with a tolerance, both positive and negative, on either side of the desired value.

The tolerances of both the socket and strike plate may combine to affect the fit and function of the assembly. If both the socket and the strike plate are at the low end of the acceptable dimension, or the minimum acceptable value, the fit of the assembly within the automated handler may be adversely affected. A similar situation may occur if both the socket and the strike plate are at the upper or maximum acceptable value. Such a situation may result in longer pins being needed to effectively test the IC, as the pins on the strike plate often pass through the socket to mate with the handling equipment. In addition, the solution is not ideal for high speed interfaces because the probe pins are long, adversely affecting signal integrity.

Automated handler manufacturers do not typically manufacture both of these parts. Most fabricate the socket, but not the strike plate. The strike plate works with the chuck on the test handler. This may further increase the likelihood of a tolerance problem.

There is a need in the art for an integrated socket and strike plate that provides shorter pins for top testing and reduces the likelihood of tolerance build up. In addition, there is a need in the art for an integrated socket and strike plate that may be used with any automated handler.

### SUMMARY

Embodiments contained in the disclosure provide an apparatus for facilitating testing of an electronic device. The apparatus includes a strike plate with an integrated socket. This is in contrast to the separate strike plate and socket typically found. Alignment dowels are located on an outside rim of the integrated strike plate and socket. Shims are located in a recess in the outside rim of the integrated strike plate and socket and may be used to adjust the height of the assembly to facilitate handling by an automated test handler.

A further embodiment provides an apparatus for facilitating testing of an electronic device. The apparatus includes an integrated strike plate socket that has a socket adapted to receive an electronic device. The electronic device may be an integrated circuit (IC) or a memory. The apparatus further includes a memory nest assembly having a receptacle for retaining an electronic device to be tested. In addition, the assembly is formed to mate with the socket on the integrated strike plate.

A still further embodiment provides a method for testing an electronic device. The device to be tested is installed in a memory nest, and may be a memory, or an IC. The memory nest is then aligned with an integrated strike plate socket and the fit is checked. The fit is aligned using alignment dowels located on the outside rim of the integrated strike plate socket. Vertical height (Z-height) may be adjusted using shims that are integral to the integrated strike plate socket and are located in the outside rim of the integrated strike plate. The completed test assembly is then passed to an automatic test handler for testing.

### BRIEF DESCRIPTION OF THE DRAWINGS

FIG. 1 illustrates a printed circuit board (PCB) and Integrated Strike Plate (ISP) socket, in accordance with embodiments described herein.

FIG. 2 shows a side view of a PCB, ISP socket, and memory nest assembly in accordance with embodiments described herein.

FIG. 3 depicts the assembly steps prior to automated handler testing, in accordance with an embodiment described herein.

FIG. 4 is a flowchart of a method of using an integrated strike plate socket, in accordance with embodiments described herein.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

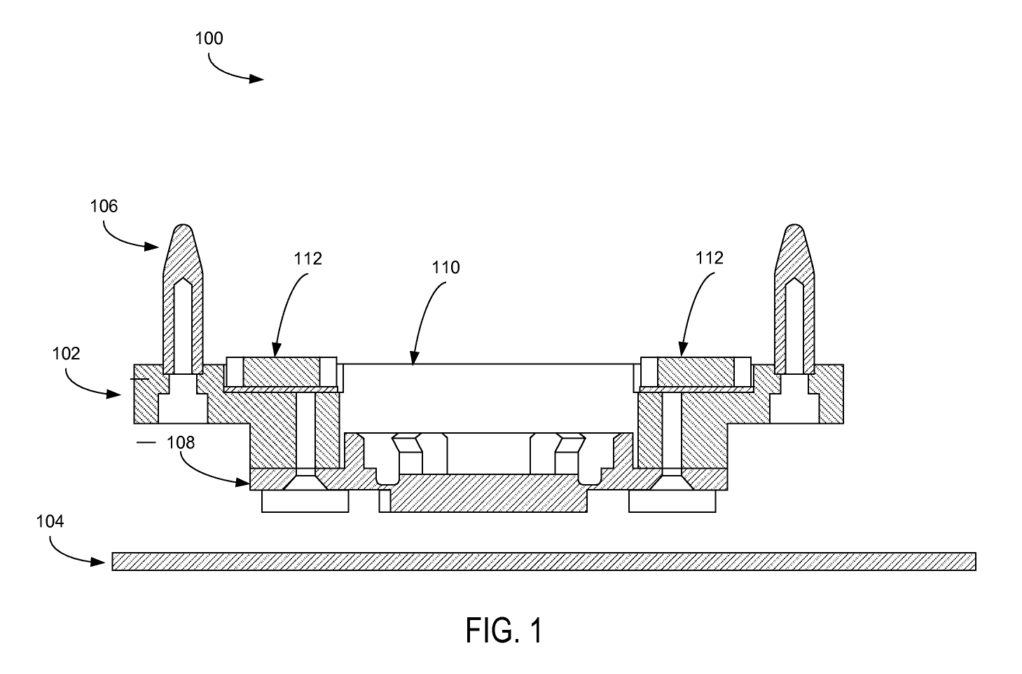

FIG. 1 illustrates an assembly 100 for use with an automated handler. The integrated strike plate socket 102 is depicted in relation to a PCB 104. Integrated strike plate socket 102 incorporates alignment dowels 106 and strike plate 108. Alignment dowels 106 are integrated into integrated strike plate socket 102 and facilitate work press alignment. Socket 110 forms a part of the integrated strike plate socket. The footprint of socket 110 is sufficient to clear any existing components already installed on PCB 104. Shims 112 allow for precise adjustment in relation to a memory nest and enable precise Z-height adjustments. Furthermore, shims 112 may be strategically placed to avoid existing features in socket 102.

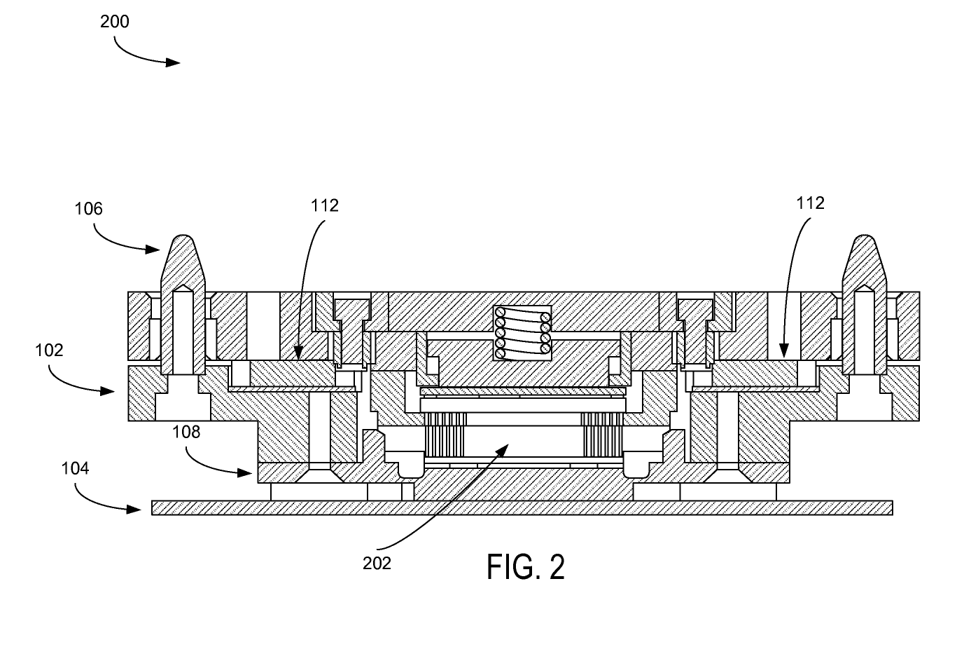

FIG. 2 shows a side view of an assembly 200 incorporating an integrated strike plate socket 102 and PCB 104. The assembly 200, has a memory nest 202 installed in integrated strike plate socket 102 ready for testing. FIG. 2 also depicts how the alignment dowels 106 provide for controlled and precise alignment with memory nest 202. The strike plate portion 108 of integrated strike plate socket 102 may be seen at the bottom of the assembly 200, above PCB 104.

The features illustrated in FIG. 2 provide numerous advantages. The memory probe nest 202 may be used to house a memory device of PCB interposer. Furthermore, the design of memory probe nest 202 allows use of shorter probe pins, giving a shorter signal path and improved signal integrity. As a result, a compound work press assembly is directly aligned to the socket.

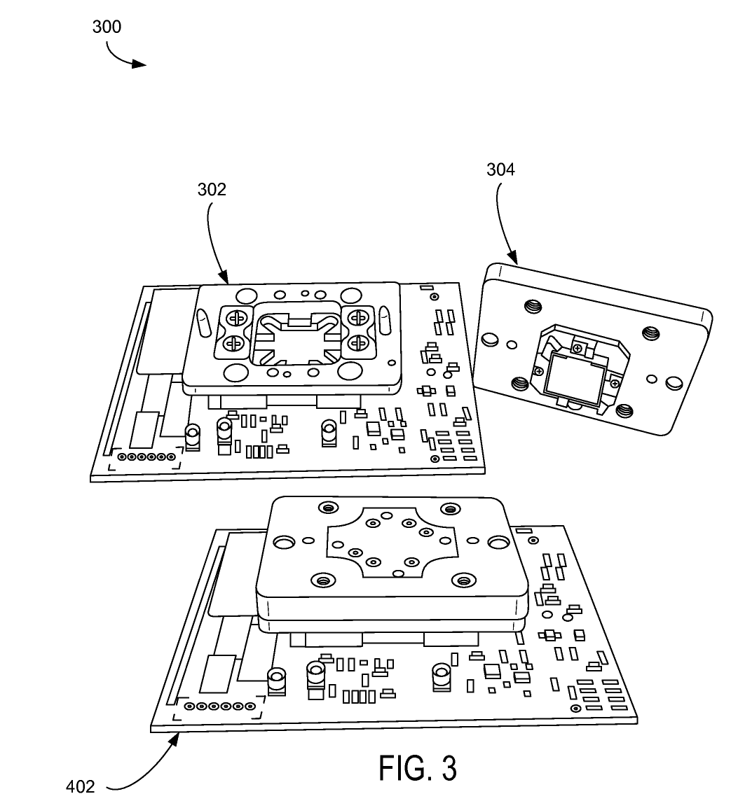

FIG. 3 shows the integrated strike plate socket and memory nest prior to assembly for testing. Socket 302 is placed on a PCB. Memory nest 304 is shown to the side in the first picture and has not yet been assembled. The lower picture shows the assembly 300 with socket 302 closest to the PCB and memory nest 304 aligned with socket 302. The completed assembly 300 is then ready for delivery to an automated handler for automated testing.

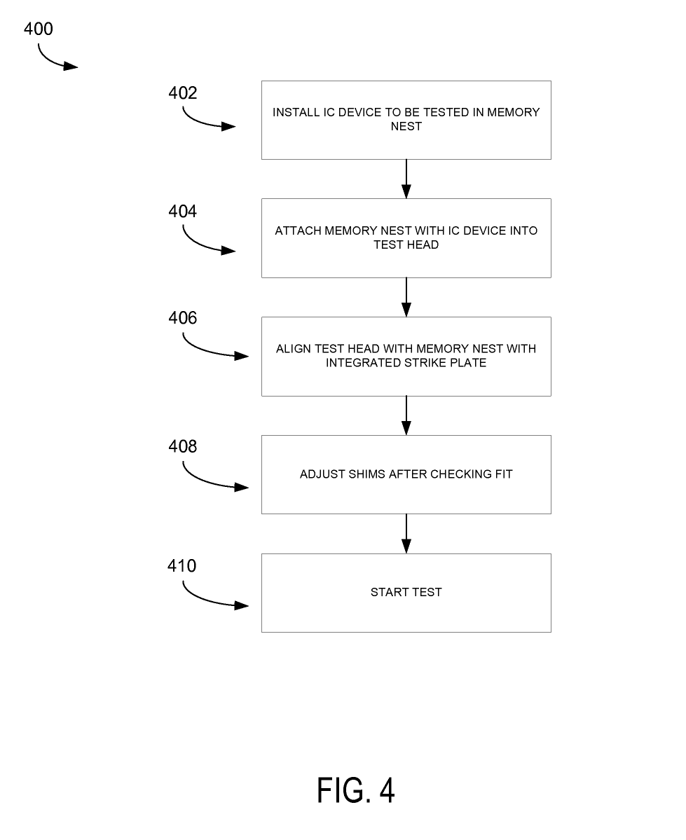

FIG. 4 is a flowchart of a method of using an integrated strike plate socket in conjunction with an automated test handler to perform testing of an IC or other device. The method 400, begins when the IC device is installed in the memory nest in step 402. The memory nest with IC device is then placed into the test head in step 404. In step 406 the test head with memory nest is aligned with the integrated strike plate. Alignment dowels 106 facilitate proper alignment. Step 408 provides for adjusting shims 112 after checking the fit of the memory nest and integrated strike plate. Testing begins in step 410.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. An apparatus for facilitating testing of an electronic device, comprising:
a strike plate;
a socket integrated into the strike plate;
alignment dowels located on an outside rim of the integrated strike plate and socket; and
a shim located in a recess in the outside rim of the integrated strike plate and socket.

2. The apparatus of claim 1, further comprising at least two alignment dowels located on opposite sides of the outside rim of the integrated strike plate and socket.

3. The apparatus of claim 1, further comprising at least two shims located in a recess in the outside rim of the integrated strike plate and socket.

4. The apparatus of claim 1 further comprising at least two alignment dowels located on opposite sides of the outside rim of the integrated strike plate socket and at least two shims located in a recess in the outside rim of the integrated strike plate socket.

5. The apparatus of claim 1, wherein the socket is shaped to accommodate a memory nest.

6. The apparatus of claim 1, wherein the socket is shaped to accommodate an integrated circuit (IC) device.

7. An apparatus for facilitating testing of an electronic device, comprising:
an integrated strike plate socket having a socket adapted to receive an electronic device to be tested; and
a memory nest assembly having a receptacle for retaining an electronic device to be tested and formed to mate with the socket on the integrated strike plate.

8. The apparatus of claim 7 wherein the integrated strike plate socket incorporates alignment dowels.

9. The apparatus of claim 7, wherein the integrated strike plate socket incorporates shims.

10. The apparatus of claim 7, wherein the integrated strike plate socket and memory nest are adapted to receive an integrated circuit device.

11. The apparatus of claim 7, further comprising at least two alignment dowels located on opposite sides of an outside rim of the integrated strike plate socket and at least two shims located in a recess in the outside rim of the integrated strike plate socket.

12. A method of testing an electronic device, comprising:
installing an electronic device to be tested in a memory nest;
attaching the memory nest with installed electronic device into a test head;
aligning the test head with memory nest with integrated strike plate;
adjusting shims after checking fit of the test head with memory nest with integrated strike plate;
loading the secured memory nest and integrated strike plate into an automated test handler for testing.

13. The method of claim 12 wherein aligning the memory nest and the integrated strike plate socket is accomplished using alignment dowels on the integrated strike plate.

14. The method of claim 12 further comprising: adjusting a height of the memory nest within the integrated strike plate socket using shims.

15. The method of claim 12, wherein the electronic device to be tested is an integrated circuit (IC).

16. The method of claim 12, wherein the electronic device to be tested is a memory device.

17. The method of claim 12, further comprising: probing the electronic device under test during automated test handler testing to verify performance.
